(19) United States
(12) Patent Application Publication
(10) Pub. No.: US 2014/0021491 A1
(43) Pub. Date: Jan. 23, 2014

(54) MULTI-COMPOUND MOLDING

(71) Applicant: CARSEM (M) SDN. BHD., Ipoh (MY)

(72) Inventors: Chan Boon Meng, Ipoh (MY); Lee Yoke Foo, Ipoh (MY); Kum Chun Cheong, Ipoh (MY)

(73) Assignee: CARSEM (M) SDN. BHD., Ipoh (MY)

(21) Appl. No.: 13/752,127

(22) Filed: Jan. 28, 2013

(30) Foreign Application Priority Data
Jul. 18, 2012 (MY) PI2012700475

(51) Int. Cl. H01L 33/54; H01L 33/00

(52) U.S. Cl. CPC H01L 33/54; H01L 33/005
USPC 257/82; 438/25

(57) ABSTRACT

In certain embodiments, a semiconductor package includes a leadframe, a light emitter die disposed on the leadframe, and a light detector die disposed on the leadframe adjacent to the light emitter die. In some embodiments, a first transparent molding compound is disposed over the light emitter die and a second transparent molding compound is disposed over the light detector die. The first and second transparent molding compound may be disposed such that a space between them forms a cavity between the die and above the leadframe. In other embodiments a transparent molding compound is disposed simultaneously over the light emitter and light detector die and a subsequent material removal process forms a cavity within the compound between the die. In both embodiments, an opaque molding compound is disposed in the cavity between the die, and is configured to block optical cross-talk between the light emitter and light detector die.

### CROSS-REFERENCES TO RELATED APPLICATIONS

This application claims priority to Malaysian Application No. PI2012700475, filed Jul. 18, 2012, which is referred to and incorporated herein by reference in its entirety.

### FIELD OF THE INVENTION

The present invention relates in general to semiconductor packaging and, more particularly, to semiconductor packages having a transparent molding compound and an opaque molding compound combined into a molded package.

### BACKGROUND

Integrated circuit (IC) optical sensors (e.g., proximity sensors) typically include a light emitter die and a light detector die mounted on a leadframe in a semiconductor package. Many current processes produce optical sensors with poor optical isolation and unfavorable noise (e.g., light leakage) between the light emitter and light detector dies, among other poor performance characteristics. Furthermore, current molding processes utilize slow and inefficient human-operated manual casting methods that produce low and inconsistent manufacturing yields. New methods are desired that produce optical sensors with excellent cross-talk characteristics using faster and more efficient means for high volume production.

### SUMMARY

In certain embodiments a semiconductor package includes a leadframe, a light emitter die disposed on the leadframe, and a light detector die disposed on the leadframe adjacent to the light emitter die. A transparent (e.g., light transmissive) molding compound is disposed over the light emitter die and the light detector die. A cavity is formed in the transparent molding compound between the die and above the leadframe. At least one additional cavity may be formed in the transparent mold compound and may be disposed on an edge of the package. An opaque molding compound is disposed in the cavities formed in the transparent molding compound, wherein the opaque molding compound fills the cavities and is configured to block optical cross talk between the light emitter and light detector.

In an embodiment, the opaque material is substantially flush with respect to the top surface of the transparent mold compound.

In another embodiment, the opaque mold compound may be additionally disposed over the transparent mold compound. A portion of the opaque mold compound covering the transparent mold compound may be selectively removed, forming apertures in the transparent mold compound.

In yet another embodiment, cavities may be formed on all four edges of the package and filled with opaque mold compound.

In another embodiment, there may be a ledge cavity formed adjacent to the cavity between the light emitter and light detector die. The opaque material may also be disposed within the ledge cavity.

In yet another embodiment, the cavity formed between the light emitter and light detector die may have at least one sloped wall.

In accordance with yet another embodiment of the present invention a semiconductor package includes a leadframe, a light emitter die disposed on the leadframe, and a light detector die disposed on the leadframe adjacent to the light emitter die. A transparent (e.g., light transmissive) molding compound is disposed over the light emitter die and the light detector die. A cavity with at least one sloped wall is formed in the transparent molding compound between the die and above the leadframe. An opaque molding compound is disposed in the cavity formed in the transparent molding compound, wherein the opaque molding compound fills the cavity and is configured to block optical cross talk between the light emitter and light detector.

In an embodiment, the opaque material is substantially flush with respect to the top surface of the transparent mold compound.

In another embodiment, the opaque mold compound may be additionally disposed over the transparent mold compound. A portion of the opaque mold compound covering the transparent mold compound may be selectively removed, forming apertures in the transparent mold compound.

In yet another embodiment, cavities may be formed on all four edges of the package and filled with opaque mold compound.

In another embodiment, there may be a ledge cavity formed adjacent to the cavity between the light emitter and light detector die. The opaque material may also be disposed within the ledge cavity.

In yet further embodiments, a method of forming a semiconductor package includes providing a leadframe, placing a first die on the leadframe, and placing a second die on the leadframe, where the first and second die are placed adjacent to each other. The method further includes disposing a transparent molding compound over all die on the leadframe in a unitary operation and selectively removing it, forming a cavity between the die. At least one additional cavity may be formed in the transparent mold compound and may be disposed on an edge of the package. An opaque molding compound is disposed in the cavities formed in the transparent molding compound, wherein the opaque molding compound fills the cavities and is configured to block optical cross talk between the light emitter and light detector.

In another embodiment, method may include embodiments wherein the cavities formed on the edge of the package may be wider than the cavity formed between the die.

In yet another embodiment, the method may include additionally disposing the opaque mold compound over the transparent mold compound. A portion of the opaque mold compound covering the transparent mold compound may be selectively removed, forming apertures in the transparent mold compound.

In another embodiment, the method may include forming street cavities in the transparent mold compound disposed on each of the horizontal and vertical streets and above the leadframe.

The method may further include disposing opaque mold compound in the plurality of street cavities.

In yet another embodiment, the method may include forming a ledge cavity adjacent to the cavity between the light emitter and light detector die. The opaque material may also be disposed within the ledge cavity.

In another embodiment, the method may include forming the cavity between the die with at least one sloped wall.

In yet further embodiments, a method of forming a semiconductor package includes providing a leadframe, placing a first die on the leadframe, and placing a second die on the leadframe, where the first and second die are placed adjacent to each other. The method further includes disposing a transparent molding compound over all die on the leadframe in a unitary operation and selectively removing it, forming a cavity having at least one sloped wall between the die. An opaque molding compound is disposed in the cavity formed in the transparent molding compound, wherein the opaque molding compound fills the cavity and is configured to block optical cross talk between the light emitter and light detector.

In another embodiment, the method may include forming street cavities in the transparent mold compound disposed on each of the horizontal and vertical streets and above the leadframe. The method may further include disposing opaque mold compound in the plurality of street cavities.

In yet another embodiment, the method may include forming a ledge cavity adjacent to the cavity between the light emitter and light detector die. The opaque material may also be disposed within the ledge cavity.

### BRIEF DESCRIPTION OF THE DRAWINGS

FIG. 1A is a simplified diagram of a semiconductor package including a first die attached to a leadframe, according to an embodiment of the invention;

FIG. 1B is a simplified diagram of a semiconductor package including first and second die attached to a leadframe, according to an embodiment of the invention.

FIG. 1C is a simplified diagram of a semiconductor package with bond wires attaching the first and second die to the leadframe, according to an embodiment of the invention;

FIG. 1D is a simplified diagram of a semiconductor package with a transparent compound disposed over the first and second die with a cavity therebetween, according to an embodiment of the invention;

FIG. 1E is a simplified diagram of a semiconductor package with an opaque compound disposed around the first and second transparent compounds and filling the cavity therebetween, according to an embodiment of the invention;

FIG. 1F is a simplified diagram of a plurality of completed packages, according to an embodiment of the invention;

FIG. 1G is a simplified diagram of a singulated and completed package, according to an embodiment of the invention;

FIG. 2 is a simplified flow diagram illustrating aspects of a method of forming a semiconductor package, according to an embodiment of the invention;

FIG. 3A is a simplified diagram of a semiconductor package with a transparent compound disposed over the first and second die with a cavity therebetween, according to an embodiment of the invention;

FIG. 3B is a simplified diagram of a semiconductor package with an opaque compound disposed around the transparent compound and filling the cavity therebetween, according to an embodiment of the invention;

FIG. 3C is a simplified diagram of a semiconductor package with the opaque compound disposed around the transparent compound and around dome-shaped members, according to an embodiment of the invention;

FIG. 4A is a simplified diagram illustrating a top view of a transparent compound cavity mold, according to an embodiment of the invention;

FIG. 4B is a simplified diagram illustrating a top view of a transparent compound cavity mold, according to an embodiment of the invention;

FIG. 4C is a simplified diagram illustrating a top view of a transparent compound cavity mold, according to an embodiment of the invention;

FIG. 4D is a simplified diagram illustrating a top view of a transparent compound cavity mold, according to an embodiment of the invention;

FIG. 5A is a simplified diagram illustrating a perspective view of a semiconductor package, according to an embodiment of the invention;

FIG. 5B is a simplified diagram illustrating a perspective view of a semiconductor package, according to an embodiment of the invention;

FIG. 5C is a simplified diagram illustrating a perspective view of a semiconductor package, according to an embodiment of the invention; and

FIG. 5D is a simplified diagram illustrating a perspective view of a semiconductor package, according to an embodiment of the invention;

FIG. 6 is a simplified diagram illustrating the function of a proximity sensor with a transparent cover;

FIG. 7A is a simplified diagram illustrating a cross-sectional view of an embodiment of the invention with trapezoidally shaped transparent cavity blocks;

FIG. 7B is a simplified diagram illustrating a top view of an embodiment of the invention with trapezoidally shaped transparent cavity blocks;

FIG. 8 is a simplified diagram illustrating a cross-sectional view of an embodiment of the invention with trapezoidally shaped transparent cavity blocks;

FIG. 9 is a simplified flow diagram illustrating aspects of a method of forming a semiconductor package, according to an embodiment of the invention;

FIG. 10A is a simplified diagram illustrating a perspective view of an embodiment of the invention where the entire leadframe is over molded with transparent mold compound;

FIG. 10B is a simplified diagram illustrating a perspective view of an embodiment of the invention where the entire leadframe is over molded with transparent mold compound after the selective removal process;

FIG. 11 is a simplified diagram illustrating a perspective view of an embodiment of the invention illustrating a sensor package with apertures;

FIG. 12 is a simplified diagram illustrating a cross-sectional view of an embodiment of the invention with trapezoidally shaped transparent cavity blocks;

FIG. 13 is a simplified diagram illustrating a cross-sectional view of an embodiment of the invention with trapezoidally shaped transparent cavity blocks and a subsequent opaque molding process;

FIG. 14 is a simplified diagram illustrating a cross-sectional view of an embodiment of the invention with trapezoidally shaped transparent cavity blocks;

FIG. 15 is a simplified diagram illustrating a cross-sectional view of an embodiment of the invention with trapezoidally shaped transparent cavity blocks and a subsequent opaque molding process;

FIG. 16A is a simplified diagram illustrating a cross-sectional view of an embodiment of the invention with cubically shaped transparent cavity blocks;

FIG. 16B is a simplified diagram illustrating a cross-sectional view of an embodiment of the invention with cubically shaped transparent cavity blocks and a reduced transmitting aperture;

FIG. 17 is a simplified diagram illustrating a cross-sectional view of an embodiment of the invention with cubically shaped transparent cavity blocks and reduced transmitting and receiving apertures;

FIG. 18 is a simplified diagram illustrating a cross-sectional view of an embodiment of the invention with semi-trapezoidally shaped transparent cavity blocks;

FIG. 19 is a simplified diagram illustrating a cross-sectional view of an embodiment of the invention with one semi-trapezoidally shaped transparent cavity block and one trapezoidally shaped cavity block;

FIG. 20 is a simplified diagram illustrating a cross-sectional view of an embodiment of the invention with cubically shaped transparent cavity blocks;

FIG. 21 is a simplified diagram illustrating a cross-sectional view of an embodiment of the invention with semi-trapezoidally shaped transparent cavity blocks;

FIG. 22 is a simplified diagram illustrating a cross-sectional view of an embodiment of the invention with semi-trapezoidally shaped transparent cavity blocks and a subsequent opaque molding process;

FIG. 23 is a simplified diagram illustrating a cross-sectional view of an embodiment of the invention with trapezoidally shaped transparent cavity blocks;

FIG. 24 is a simplified diagram illustrating a cross-sectional view of an embodiment of the invention with trapezoidally shaped transparent cavity blocks and a subsequent opaque molding process;

FIG. 25 is a simplified diagram illustrating a cross-sectional view of an embodiment of the invention with semi-trapezoidally shaped transparent cavity blocks, a subsequent opaque molding process and a subsequent aperture formation process;

FIG. 26 is a simplified diagram illustrating a perspective view of an embodiment of the invention;

FIG. 27 is a simplified flow diagram illustrating aspects of a method of forming a semiconductor package, according to an embodiment of the invention;

FIG. 28 is a simplified flow diagram illustrating aspects of a method of forming a semiconductor package, according to an embodiment of the invention;

### DETAILED DESCRIPTION

Embodiments of the present invention include a multi-compound molding process to encapsulate light emitter die and light detector die within separated transparent compounds in a semiconductor package. The process further includes molding a barrier wall between the light emitter and light detector dies, as well as on all four sides of the package, utilizing an opaque molding compound. The opaque compound helps to eliminate optical cross talk between the light emitter and detector dies.

More generally, certain embodiments of the present invention include a semiconductor package comprising a leadframe, a light emitter die disposed on the leadframe, and a light detector die disposed on the leadframe adjacent to and spaced from the light emitter die. A first transparent molding compound is disposed over the light emitter die, where the first transparent molding compound encapsulates the light emitter die. A second transparent molding compound is disposed over the light detector die, where the second transparent molding compound encapsulates the light detector die. The first transparent molding compound and the second transparent molding compound are disposed such that the space between them forms a cavity above the leadframe. An opaque molding compound is disposed in the cavity between the first and second transparent molding compounds, wherein the opaque molding compound fills the cavity and is configured to block optical cross talk between the light emitter and light detector within the same package.

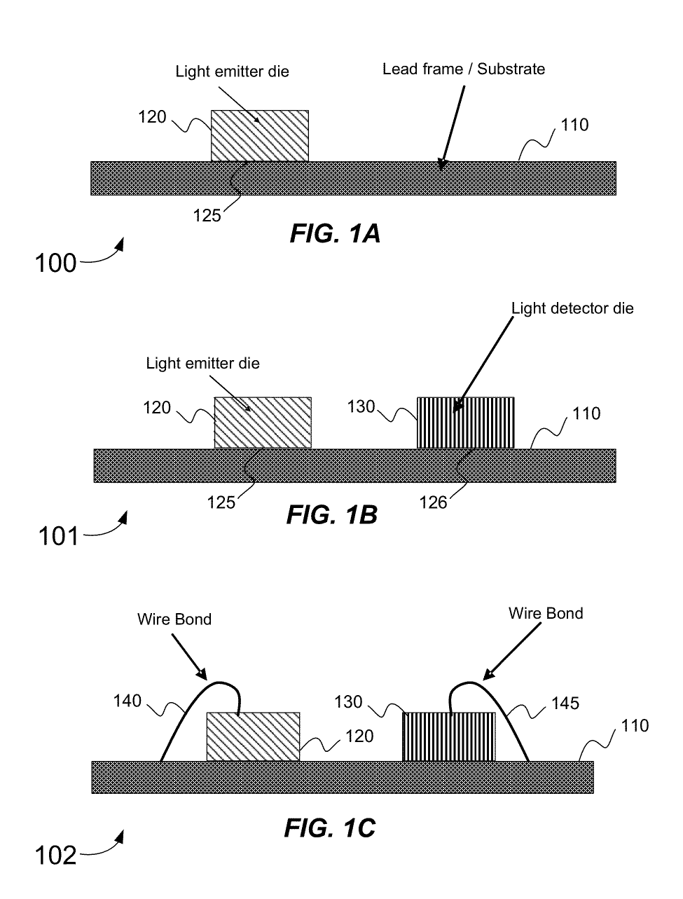

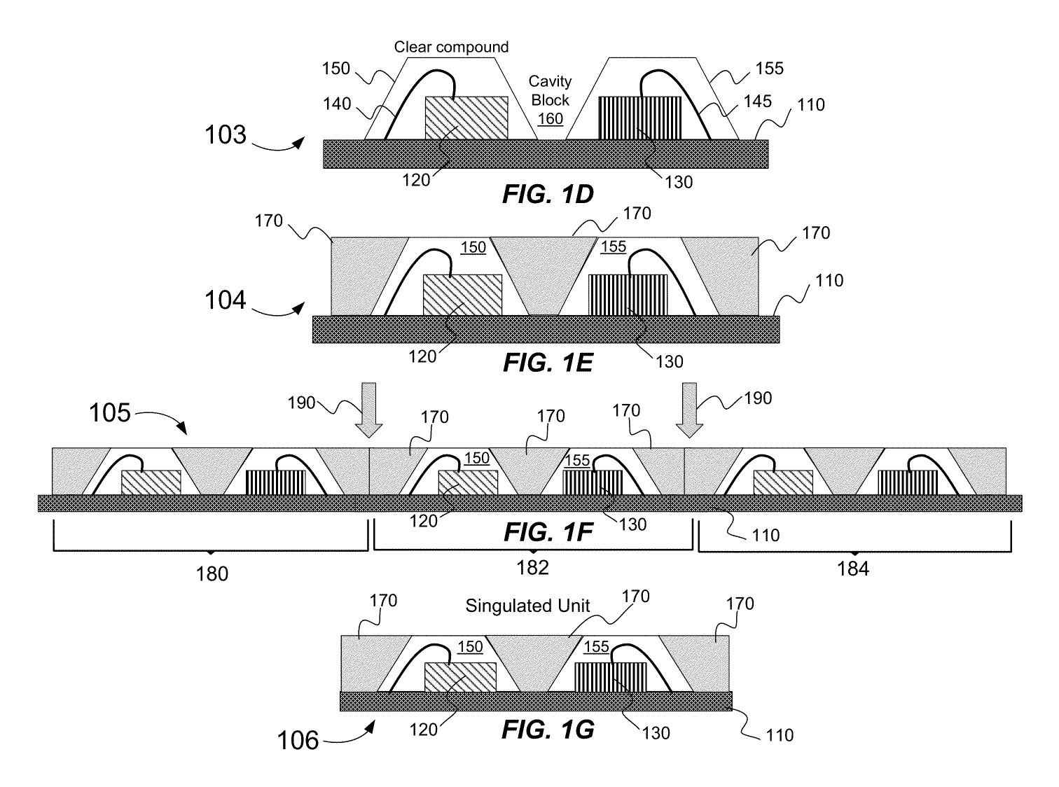

FIG. 1A is a simplified diagram of a semiconductor package 100 including a first die attached to a leadframe, according to an embodiment of the invention. The semiconductor package 100 includes a first die 120 and a leadframe 110. Alternatively, the semiconductor package 100 can include a substrate 110 in lieu of the leadframe 110. In some cases, the first die 120 can be an optoelectronic device such as a light emitter (i.e., optical transmitter). Some typical light emitters can include, but are not limited to, light emitting diodes (LEDs) (e.g., organic LEDs, bulk-emitting LEDs, quantum dot LEDs, super-luminescent LEDs, etc.), lasers, photodiodes, and the like. The first die can be affixed to the leadframe 110 by a die attachment compound 125 disposed between the bottom of the first die 120 and the leadframe 110. The attachment compound can be any suitable epoxy, which can include conducting epoxies (e.g., high temperature resistant, silver-filled, etc.) or non-conducting epoxies (e.g., electrically insulative), or other suitable bonding agents including solder. Leadframes are typically used to electrically and physically connect integrated circuits (e.g., light emitter die) to printed circuit boards.

FIG. 1B is a simplified diagram of a semiconductor package 101 including first and second die attached to a leadframe, according to an embodiment of the invention. The semiconductor package 100 includes a first die 120, second die 130, and a leadframe 110. Alternatively, the semiconductor package 100 can include a substrate 110 in lieu of the leadframe 110. The first die 120 is discussed above with respect to FIG. 1A. In certain cases, the second die 130 can be an optoelectronic device such as a light detector (i.e., optical receiver). Some typical light receivers (i.e., optoelectronic receivers) can include, but are not limited to, photodetectors, PIN diodes, charged-coupled devices (CCD), phototransistors, quantum dot photoconductors, and the like. The second die can be affixed to the leadframe 110 by a die attachment compound 126 disposed between the bottom of the second die 130 and the leadframe 110. The attachment compound can be any suitable epoxy, which can include conducting epoxies (e.g., high temperature resistant, silver-filled, etc.) or non-conducting epoxies (e.g., electrically insulative), or other suitable bonding agents including solder.

FIG. 1C is a simplified diagram of a semiconductor package 102 with bond wires 140, 145 attaching the first die 120 and the second die 130 to the leadframe 110, according to an embodiment of the invention. The first die 120 and second die 130 are attached to the leadframe 110 as discussed above with respect to FIGS. 1A-1B. Wire bonding is a typical method for making electrical interconnections between an integrated circuit (e.g., first die 120 or second die 130) and a leadframe 110 or a printed circuit board (not shown). The bond wires 140, 145 can be made of conductive metals including, but not limited to, copper, gold, aluminum, and alloys thereof. In some cases, wire bonds can range from tens of micrometers to hundreds of micrometers in thickness depending on the size of the die, package, and distance between the contact points. In some embodiments, the bond wires 140, 145 are set in place by ball bonding or wedge bonding processes, which can include varying combinations of heat, pressure, and/or ultrasonic energy to form a weld.

FIG. 1D is a simplified diagram of a semiconductor package 103 with a transparent compound 150, 155 disposed over the first and second die 120, 130 and a cavity 160 therebetween, according to an embodiment of the invention. The transparent compound 150 encapsulates the first die. Similarly, the transparent compound 155 encapsulates the second die 130. The transparent compounds 150, 155 (or transparent molding compounds 150, 155) may comprise the same or different chemical compounds. The transparent compounds (i.e., transparent molding compounds) 150, 155, are disposed such that the space between them forms a cavity 160 above the leadframe 110.

In some embodiments, a cross section for both transparent compounds 150, 155 is in a shape of a trapezoid, where each trapezoid includes a top portion, a base portion, an inner side portion, and an outer side portion. The top portion can be shorter in length than the base portion, and the inner side portions of the first and second transparent molding compounds 150, 155 face each other and are configured such that the cavity 160 formed between them forms a wedge shape. In some cases, the wedge shape forms an inverted trapezoid, where a top portion of the inverted trapezoid is longer than a base portion of the inverted trapezoid and where the top portion of the inverted trapezoid is flush with the top portions of the first and second transparent molding compounds. The top portions are substantially unobstructed to allow for a substantially uninhibited transfer of light between an internal and external region of both the first and second transparent molding compounds 150, 155.

The trapezoid shape allows a mold that is used to form the first and second transparent molding compounds 150, 155 to be easily removed after a formation process. Without the trapezoid shape, the first and second transparent molding compounds 150, 155 may be detached from a surface of the leadframe 110 during removal of the mold due to friction.

The first die 120 and second die 130 are attached to the leadframe 110 via bond wires 140, 145 as discussed above with respect to FIGS. 1A-1C. In some embodiments, the multi-compound molding process described herein involves first encapsulating the light emitter die 120 in transparent compound 150 and the light detector die 130 in the transparent compound 155. In some aspects, the transparent compounds 150, 155 are optically transmissive materials that can be comprised of a light transmissive epoxy, resin, or other polymer. The transparent compounds (i.e., transparent molding compounds) can be formed by cast molding, transfer molding, or other suitable methods of encapsulation. In some cases, the optically transmissive materials can be inserted into a mold as a fluid, which hardens and forms a solid when cured. In other cases, the transparent molding compounds may be a thermosetting polymer. The transparent molding compounds 150, 155 are substantially transparent to the wavelengths of light emitted by the light emitter die 120 and detected by the light detector die 130, which can include the visible spectrum, infrared spectrum, ultra-violet spectrum, or the like. The transparent molding compounds 150, 155 may include, but are not limited to, one or more transparent resins, silicones, epoxy-silicone hybrid resins, epoxy resins with transparent fillers, transparent thermoplastics, and the like.

FIG. 1E is a simplified diagram of a semiconductor package 104 with an opaque compound 170 disposed around the first and second transparent molding compounds 150, 155 and filling the cavity 160 there between, according to an embodiment of the invention. The opaque compound 170 is configured to be directly adjacent to the transparent molding compounds 150, 155 such that there is no gap between the two.

The opaque compound 170 creates an opaque wall that prevents optical coupling (i.e., light transmission) between the light emitter die 120 and the light detector die 130. The opaque compound 170 can be an opaque epoxy (e.g., black epoxy), resin, or polymer that blocks wavelengths generated by the light emitter die 120. As described above, the opaque compound 170 is further disposed around the first and second transparent molding compounds 150, 155, where the opaque molding compound 170 is flush with respect to the top portions of the first and second transparent molding compounds 150, 155. The first and second transparent molding compounds 150, 155 and the opaque molding compound 170 can be disposed on the top surface of the leadframe 110.

In certain embodiments, a protective layer (e.g., a built-in semi-hard rubbery material or a protective replenishable thin film—not shown) is formed over the transparent encapsulant material (transparent molding compounds 150, 155) before forming the opaque compound 170 (e.g., opaque barrier walls) to fill the cavity 160. In some cases, the protective layer can be formed as part of the top mold. The protective layer can reduce surface damage and prevent mold resin or mold flashes from seeping onto the top surface of the encapsulant material during the depositing of the opaque material 170 that could degrade the transparency of the transparent molding compounds 150, 155. The opaque material 170 may include, but is not limited to, one or more black epoxy resins, reflective epoxy resins, IR blocking and/or retardant epoxy resins, reflective thermoplastic molding materials, and the like.

FIG. 1F is a simplified diagram of a plurality of completed packages 105, according to an embodiment of the invention. The plurality of completed packages 105 include completed units 180, 182, and 184, which include the first and second die 120, 130 disposed on the leadframe 110 and encapsulated by transparent molding compounds 150, 160. The opaque molding compounds 170 are disposed around the transparent molding compounds 150, 155 and fill the cavity between the transparent molding compounds 150, 155 to prevent optical cross-talk between the first and second die 120, 130. The plurality of completed units 180, 182, 184 are separated (i.e., cut) at locations 190 to create singulated units. FIG. 1G is a simplified diagram of singulated and completed package 106, according to an embodiment of the invention.

It should be appreciated that embodiments of the invention are not limited to packages that include light emitter and light detector die pairs. For example, in some embodiments a package may include more (or less) light emitter dies than light detector dies. Further, in other embodiments multiple light emitter dies may be included in a package that does not include any light detector dies, or multiple light detector dies may be included in a package that does not include any light emitter dies. Furthermore, in other embodiments some or all of the dies may be neither light emitters nor light detector dies.

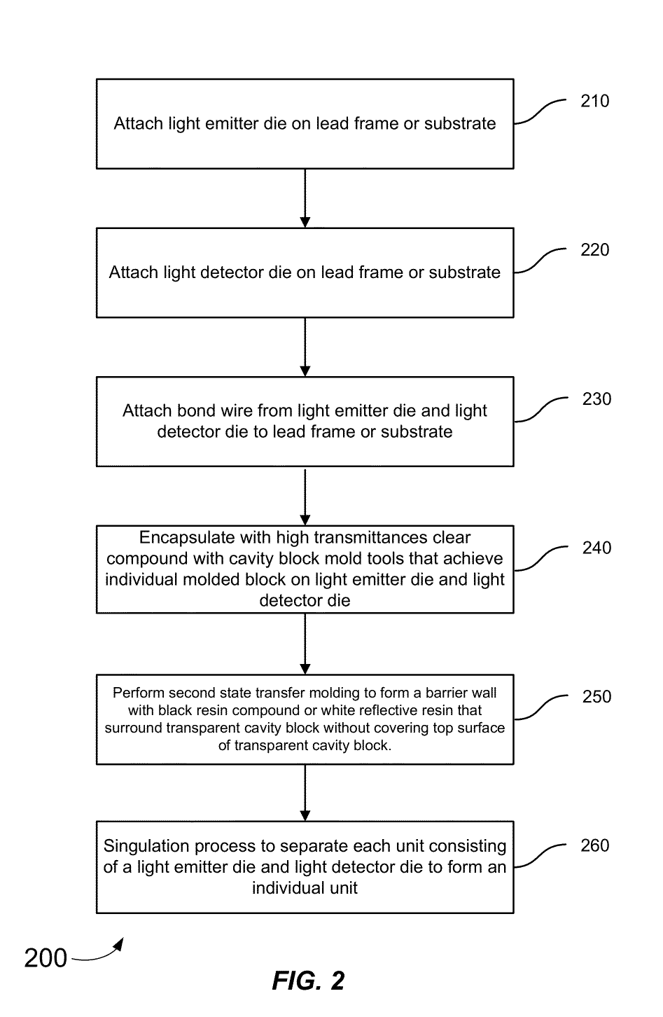

FIG. 2 is a simplified flow diagram illustrating aspects of a method 200 of forming a semiconductor package, according to an embodiment of the invention. In one embodiment, the method 200 is a manufacturing process. The method 200 includes attaching a first die to a leadframe (210). In some cases, the first die can be an optoelectronic device such as a light emitter (i.e., optical transmitter). The first die can be affixed to the leadframe by a die attachment compound disposed between the bottom of the first die and the leadframe. In some cases, the first die can be attached to a substrate in lieu of the leadframe.

Referring back to FIG. 2, the method 200 further includes attaching a second die on the leadframe (220). In certain cases, the second die can be an optoelectronic device such as a light detector (i.e., optical receiver). The second die can be affixed to the leadframe by a die attachment compound disposed between the bottom of the second die and the leadframe.

The method 200 continues with attaching bond wires from the light emitter die and light detector die to the leadframe (230). The bond wires can be made of conductive metals. The bond wires can be set in place by ball bonding, wedge bonding, or other processes that would be appreciated by one of ordinary skill in the art with the benefit of this disclosure.

The method 200 continues with encapsulating both the light emitter die and light detector die with a transparent molding compound comprising high light transmittance properties (240). In some cases, the mold can be created with cavity block mold tools to achieve individual molded blocks on each die. The method 200 further includes performing a second state transfer molding to form a barrier wall surrounding each transparent cavity block without covering the top surfaces of each of the transparent cavity blocks (250). In an alternative embodiment, the method can include depositing an opaque compound to surround both the first and second transparent compounds without covering the top surfaces of the first and second transparent compounds, where the opaque compound forms a barrier wall between the light emitter die and the light detector die, and where the barrier wall is configured to block optical cross talk between the light emitter die and light detector die. In some embodiments, the barrier wall is comprised of a black resin compound or white reflective resin surrounding the cavity block, but not covering the top surface of the transparent cavity blocks (i.e., the transparent molding compounds formed around the emitter and detector die). At (260), the method 200 further includes performing a singulation process to separate each unit consisting of the light emitter die and light detector die with dual molding processes to form an individual unit.

It should be appreciated that the specific steps illustrated in FIG. 2 provide a particular method of forming a semiconductor package, according to an embodiment of the present invention. Other sequences of steps may also be performed according to alternative embodiments. In certain embodiments, the method 200 may perform the individual steps in a different order, at the same time, or any other sequence for a particular application. Moreover, the individual steps illustrated in FIG. 2 may include multiple sub-steps that may be performed in various sequences as appropriate to the individual step. Furthermore, additional steps may be added or removed depending on the particular applications. One of ordinary skill in the art would recognize and appreciate many variations, modifications, and alternatives in light of the method 200.

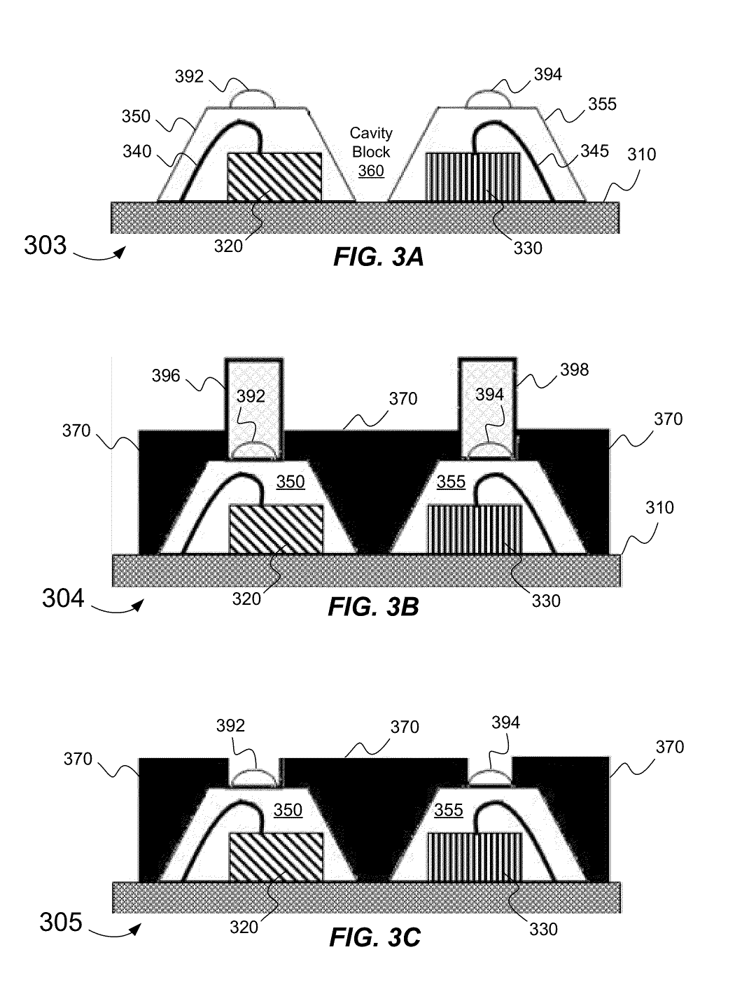

FIGS. 3A-3C are simplified diagrams of semiconductor packages at various stages of a manufacturing process in accordance with another embodiment of the invention. In these figures, dies 320, 330 are attached to a leadframe 310, and bond wires 340, 345 attach the dies 320, 330 to the leadframe 310. These steps are not separately illustrated but may be performed in a manner similar to that described above with regard to FIGS. 1A-1C and steps 210-230 of FIG. 2.

FIG. 3A is a simplified diagram of a semiconductor package 303 with a transparent compound 350, 355 disposed over the first and second die 320, 330 and a cavity 360 therebetween, according to an embodiment of the invention. The semiconductor package 303 is similar to the semiconductor package 103 described above with regard to FIG. 1D and may include one or more of the same features. In this embodiment, however, dome-shaped members 392, 394 are formed on top of the transparent compound 350, 355. The dome-shaped members 392, 394 may comprise the same optically transmissive materials as the transparent compound 350, 355. Alternatively, the dome-shaped members 392, 394 may comprise an optically transmissive material having different optical properties than the transparent compound 350, 355. Also, the dome-shaped members 392, 394 may be formed during the same molding process as the transparent compound 350, 355 or may be formed separately. For example, in some embodiments the dome-shaped members 392, 394 may be formed separately and attached to a top surface of the transparent compound 350, 355.

Each of the dome-shaped members 392, 394 may act as a lens to converge or diverge light passing therethrough, and the dome-shaped members 392, 394 may have the same or different optical properties. For example, in some embodiments the dome-shaped member 392 may diverge light emitted from a light emitting die such as die 320, and the dome-shaped member 394 may converge light on a light detecting die such as die 330. In some embodiments, only one of the die 320, 330 may include a dome-shaped member rather than both of the die 320, 330 as illustrated in this example. Also, in some embodiments the dome-shaped members 392, 394 may be cubical or spherical rather than the dome-shape illustrated in this example.

FIG. 3B is a simplified diagram of a semiconductor package 304 with an opaque compound 370 disposed around the transparent compound 350, 355 and filling a cavity therebetween, according to an embodiment of the invention. The semiconductor package 304 is similar to the semiconductor package 104 described above with regard to FIG. 1E and may include one or more of the same features. In this embodiment, however, the opaque compound 370 covers a portion of an upper surface of the transparent compound 350, 355. A difference in height between an upper surface of the opaque compound 370 and an upper surface of transparent compound 350, 355 may vary depending on the particular application. To prevent the opaque compound 370 from covering the dome-shaped members 392, 394, pins 396, 398 cover the dome-shaped members 392, 394. The pins 396, 398 may be placed over the dome-shaped members 392, 394 either before or during the molding process that is used to form the opaque compound 370. The pins 396, 398 may be of any suitable material and may be hollow or have a hollow portion surrounding the dome-shaped members 392, 394. Also, while sides of the pins 396, 398 are substantially vertical in this example, the sides may be sloped depending on the particular application.

FIG. 3C is a simplified diagram of a semiconductor package 305 with the opaque compound 370 disposed around the transparent compound 350, 355 and around the dome-shaped members 392, 394, according to an embodiment of the invention. In these figures, the pins 396, 398 shown in FIG. 3B have been removed to expose the dome-shaped members so that light can pass therethrough.

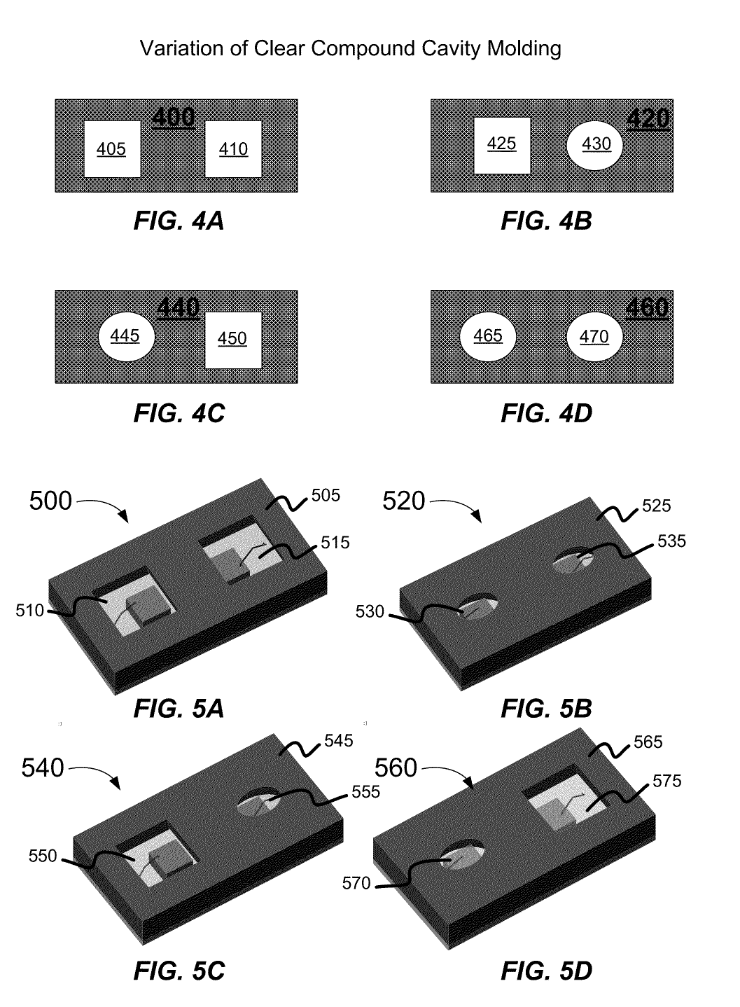

FIG. 4A is a simplified diagram illustrating a top view of a transparent compound cavity mold 400, according to an embodiment of the invention. The mold 400 includes a first transparent compound cavity molding 405 and a second transparent compound cavity molding 410. The transparent compound cavity mold 400 is used to create the transparent compound structures that encapsulate both the light emitter die and light detector die and exhibit high light transmittance properties, as further described above. In this particular embodiment, both the first transparent compound cavity molding 405 and the second transparent compound cavity molding 410 are substantially square shaped. However, other shapes, configurations, depths, materials, spacing with respect to each other, etc., can be used as needed.

FIG. 4B is a simplified diagram illustrating a top view of a transparent compound cavity mold 420, according to an embodiment of the invention. The mold 420 includes a first transparent compound cavity molding 425 and a second transparent compound cavity molding 430. The transparent compound cavity mold 420 is used to create the transparent compound structures that encapsulate both the light emitter die and light detector die and exhibit high light transmittance properties, as further described above. In this particular embodiment, the first transparent compound cavity molding 425 is substantially square shaped and the second transparent compound cavity molding 430 is substantially oval shaped. However, other shapes, configurations, depths, materials, spacing with respect to each other, etc., can be used as needed.

FIG. 4C is a simplified diagram illustrating a top view of a transparent compound cavity mold 440, according to an embodiment of the invention. The mold 440 includes a first transparent compound cavity molding 445 and a second transparent compound cavity molding 450. The transparent compound cavity mold 440 used to create the transparent compound structures that encapsulate both the light emitter die and light detector die and exhibit high light transmittance properties, as further described above. In this particular embodiment, the first transparent compound cavity molding 445 is substantially oval shaped and the second transparent compound cavity molding 450 is substantially square shaped. However, other shapes, configurations, depths, materials, spacing with respect to each other, etc., can be used as needed.

FIG. 4D is a simplified diagram illustrating a top view of a transparent compound cavity mold 460, according to an embodiment of the invention. The mold 460 includes a first transparent compound cavity molding 465 and a second transparent compound cavity molding 470. The transparent compound cavity mold 460 is used to create the transparent compound structures that encapsulate both the light emitter die and light detector die and exhibit high light transmittance properties, as further described above. In this particular embodiment, both the first transparent compound cavity molding 465 and a second transparent compound cavity molding 470 are substantially oval shaped. However, other shapes, configurations, depths, materials, spacing with respect to each other, etc., can be used as needed.

FIG. 5A is a simplified diagram illustrating a perspective view of a semiconductor package 500, according to an embodiment of the invention. The semiconductor package 500 includes a first transparent compound structure 510 encapsulating a light emitter die, a second transparent compound structure 515 encapsulating a light detector die, and an opaque mold compound 505 surrounding the first and second transparent compound structures 510, 515. As described above, the opaque mold compound 505 creates an opaque wall that prevents optical coupling between the light emitter die and the light detector die. The opaque material can be an opaque epoxy (e.g., black epoxy), resin, or polymer that blocks wavelengths generated by the light emitter die. In this particular embodiment, the opaque mold compound 505 is formed directly adjacent to the substantially square transparent molding compounds 510 and 515, but does not obstruct the top portions of each. Other shapes, configurations, depths, materials, and the like, can be used as required.

FIG. 5B is a simplified diagram illustrating a perspective view of a semiconductor package 520, according to an embodiment of the invention. The semiconductor package 520 includes a first transparent compound structure 530 encapsulating a light emitter die, a second transparent compound structure 535 encapsulating a light detector die, and an opaque mold compound 525 surrounding the first and second transparent compound structures 530, 535. As described above, the opaque mold compound 525 creates an opaque wall that prevents optical coupling between the light emitter die and the light detector die. The opaque material can be an opaque epoxy (e.g., black epoxy), resin, or polymer that blocks wavelengths generated by the light emitter die. In this particular embodiment, the opaque mold compound 525 is formed directly adjacent to the substantially square transparent molding compounds 530 and 535, but does not obstruct the top portions of each. Other shapes, configurations, depths, materials, and the like, can be used as required.

FIG. 5C is a simplified diagram illustrating a perspective view of a semiconductor package 540, according to an embodiment of the invention. The semiconductor package 540 includes a first transparent compound structure 550 encapsulating a light emitter die, a second transparent compound structure 555 encapsulating a light detector die, and an opaque mold compound 545 surrounding the first and second transparent compound structures 550, 555. As described above, the opaque mold compound 545 creates an opaque wall that prevents optical coupling between the light emitter die and the light detector die. The opaque material can be an opaque epoxy (e.g., black epoxy), resin, or polymer that blocks wavelengths generated by the light emitter die. In this particular embodiment, the opaque mold compound 545 is formed directly adjacent to the substantially square transparent molding compounds 550 and 555, but does not obstruct the top portions of each. Other shapes, configurations, depths, materials, and the like, can be used as required.

FIG. 5D is a simplified diagram illustrating a perspective view of a semiconductor package 560, according to an embodiment of the invention. The semiconductor package 560 includes a first transparent compound structure 570 encapsulating a light emitter die, a second transparent compound structure 575 encapsulating a light detector die, and an opaque mold compound 565 surrounding the first and second transparent compound structures 570, 575. As described above, the opaque mold compound 565 creates an opaque wall that prevents optical coupling between the light emitter die and the light detector die. The opaque material can be an opaque epoxy (e.g., black epoxy), resin, or polymer that blocks wavelengths generated by the light emitter die. In this particular embodiment, the opaque mold compound 565 is formed directly adjacent to the substantially square transparent molding compounds 570 and 575, but does not obstruct the top portions of each. Other shapes, configurations, depths, materials, and the like, can be used as required.

Some embodiments of the present invention include the use of light emitter die and light detector die for proximity sensor applications. These applications typically employ an emitter die that emits light energy in the infrared spectrum and a receiver die that is sensitive to the corresponding emitted infrared spectrum of the emitter die. However, this invention is not limited to the use of die that operate in the infrared spectrum and it is well known in the art that other embodiments could operate within the visible spectrum, infrared spectrum, ultra-violet spectrum, or the like.

Infrared proximity sensors can employ separately packaged emitter and detector die, or the die can be copackaged in the same physical device. Copackaging typically results in reduced cost and space, which are important advantages in today's high-density electronic products. One use of such sensors is for cellular telephones. In these applications the sensors are hidden behind a transparent cover and when they sense the phone being placed next to one's head, such as during a phone call, they signal the processor to turn off the display backlight to conserve battery power.

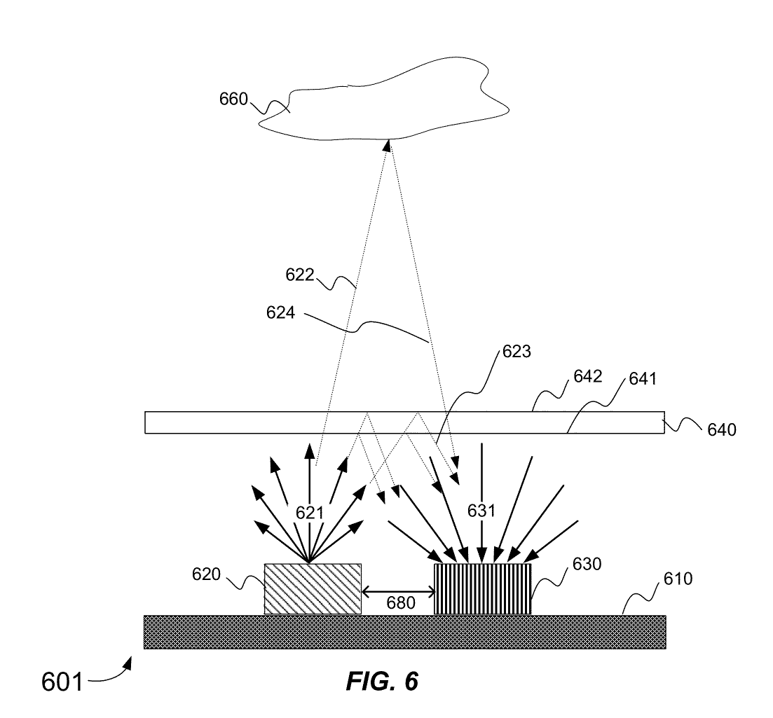

FIG. 6 depicts a typical construction of a proximity sensor 601, however it is understood that this depiction is for illustration only and other embodiments can be employed without departing from the invention herein. To operate the proximity sensor 601, a drive circuit powers an emitter die 620, which emits light energy 621 from the die surface. Typically, the emission patterns from these die are diffuse; as such, the light energy emanates from the die at many angles 621. The light energy propagates through space 622 and eventually strikes an object 660. A portion of the emitted light 624 reflects off the object (e.g., a human head) back towards the sensor. A detector die 630 is typically mounted adjacent to and in close proximity, 680, of the emitter die. Detector die are generally sensitive to light energy that impinges the die surface at any angle 631. A portion of the reflected light energy 624 is received by the detector die, which converts the light energy (photons) to a current that is proportional to the amount of photons that impinge the detector die.

Thus, proximity sensors operate based on the amount of light reflected back to the sensor from objects. The amount of reflected light can be affected by the proximity of the object to the detector and the reflectivity of the object in the spectrum of the light. The closer the object is to the emitter and the detector, the more light that is received by the detector. With regard to reflectivity, the more reflective the object in the particular spectrum, the more light that will be received by the detector. For instance, skin tissue is generally much more reflective than hair. Thus, when employed in a cellular telephone, the sensor may trigger the display to shut off earlier if the phone is placed against one's skin as compared to one's hair.

To maximize the sensitivity and effectiveness of the proximity sensor 601, it is generally desirable to isolate the detector die 630 from as much light “noise” as possible. Light noise is light that reaches the detector die that was not reflected off the object that is being sensed. If there is too much light noise, the detector will be overpowered by the noise and will not be sensitive enough to “sense” the true light signal (reflected light 624 off the object 660) and the sensor will not function properly.

Light noise can come from several sources. When the emitter 620 and detector die 630 are copackaged, great care must be taken to isolate the emitter die from the detector die within the package itself. Generally, light energy leakage within the package can be minimized using an opaque barrier between the emitter and detector die.

Similarly, light noise can also emanate from the periphery of the sensor package and impinge the detector die. For example, if the die 620, 630 are encapsulated in transparent mold compound and an opaque barrier is placed only between the emitter and detector die, then light noise can emanate from the sides of the package, reflect off internal components of the electronic device, and impinge the detector die. To mitigate against emissions from the periphery of the package, it is generally desirable to fully encapsulate the emitter die within an opaqe barrier, except for a defined “emission” aperture opposite the top surface of the die. To protect the detector die from light noise, it is generally desirable to also encapsulate it on all sides with an opaque barrier, except for a “receiving” aperture opposite the top surface of the die.

FIG. 6 shows that light noise can also be caused by a transparent cover 640 that is placed over the sensor 601 when used in mobile phone and similar applications. FIG. 6 depicts a transparent cover with two surfaces 641, 642 that may reflect light noise from the emitter 620 to the detector 630, resulting in reduced sensitivity of the detector. Depending upon the surface finish of the transparent cover the reflected light may be specular or diffuse. Thus, to improve the sensitivity and functionality of the sensor it is desirable to minimize the amount of light noise that can be reflected to the detector die from the transparent cover. One way to achieve this is by only allowing light energy that is substantially collimated and perpendicular to the die surface to leave the emitter and be received by the detector. Collimated light is comprised of light rays that are substantially parallel to one another whereas diffuse light rays are not axially aligned and propagate in myriad directions.

Finally, light noise can also emanate from the ambient environment and impinge the detector die 630, degrading the sensitivity of the detector 601. Ambient light noise can emanate from a source, like the sun or any light source that emits in the spectrum of the detector 601. To protect the detector die from this light noise it is preferable to shield the detector die from light energy that approaches from all directions and only allow light that is substantially collimated and perpendicular to the die surface to impinge the detector die. This will ensure that the detector die is preferentially sensitive to light energy reflected from the object to be sensed and a substantial amount of the diffuse light noise that approaches the sensor from myriad directions cannot impinge the detector die surface. In some embodiments the detector die may be placed in a high aspect ratio opaque cavity with a receiving aperture opposite the detector die surface. A high aspect ratio cavity may have a height that is taller than the length and width of the aperture through which light energy can pass, essentially creating an elongated “tube” with an aperture at one end and the die at the other. The higher the aspect ratio of the cavity, the more collimated and perpendicular to the die surface the light must be to impinge the die. The same high aspect ratio cavity can be employed on the emitter die to ensure that only light that is substantially collimated and perpendicular to the die surface escapes the transmitting aperture.

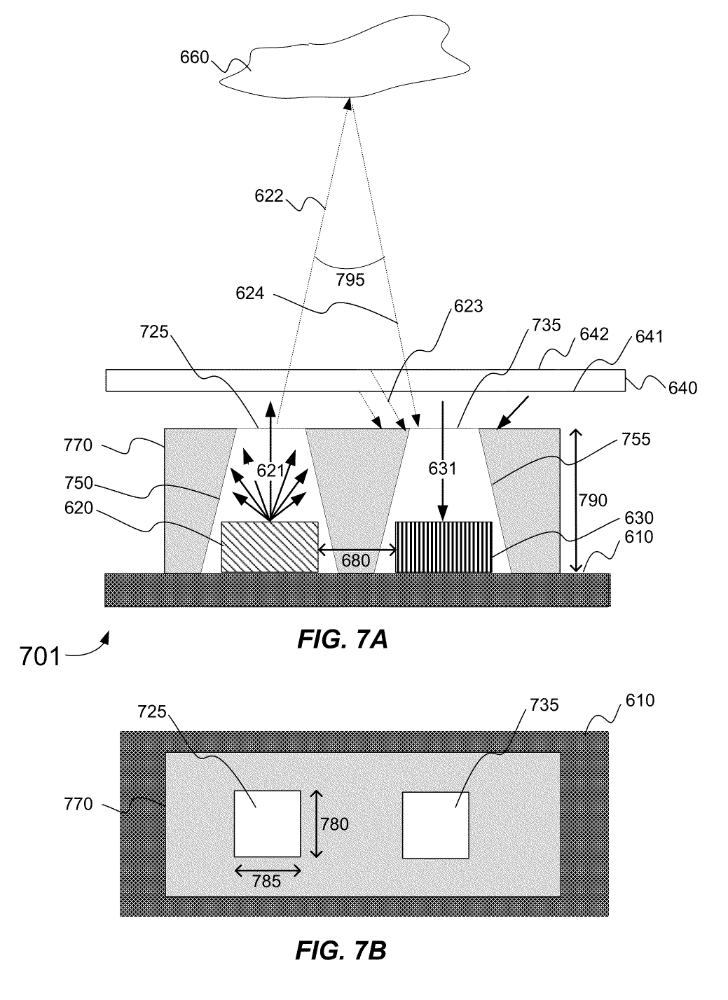

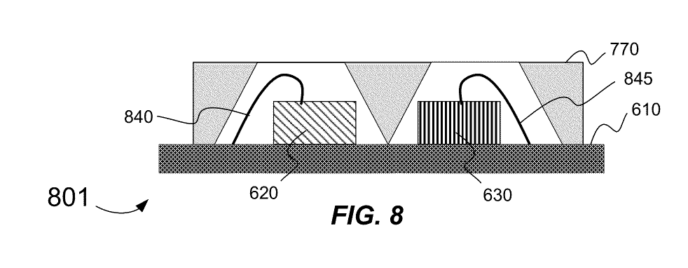

FIGS. 7A-7B depict an embodiment of a proximity sensor that overcomes the issues identified above. FIG. 7A depicts a cross-section of the sensor 701 and FIG. 7B depicts a top view of the sensor. The emitter die 620 and the detector die 630 are unchanged from FIG. 6, however, both die are encapsulated in trapezoidally shaped transparent cavity blocks, 750 and 755, respectively. The transparent mold compound cavity blocks are subsequently encapsulated in opaque mold compound, 770 with a height 790 above the leadframe 610. As shown in FIG. 7B, all four sides of each die are encapsulated in opaque mold compound creating a high aspect ratio transparent cavity block for each die. This process also creates a transmitting aperture 725 for the emitter die and a receiving aperture 735 for the detector die. One of the benefits of the trapezoidially shaped transparent mold compound 750, 755 is that it enables a large cross-section at the height of the die so each die is fully encapsulated, and a reduced cross-section at the top of the package that enables an aperture that is smaller than the size of the die. Those of skill in the art will recognize that other shapes could be used such as tapered cylinders, tapered octagons a cuboid or simply a cube, without departing from this disclosure.

The aspect ratio of the transparent cavity blocks 750, 755 is generally defined as the dimension of the height of the mold, 790 as compared to the dimensions 780, 785 of the aperture 725, 735. For example, if the height of the mold 790 is two millimeters and the length and width of the aperture 780, 785 is one millimeter, then the aspect ratio of the transparent cavity block would be 2:1. FIG. 7A shows that as the aspect ratio of the cavity block for the emitter die 620 is increased, the trend is toward only allowing light 621 to egress from the aperture 725 that is substantially collimated and perpendicular to the die. Similarly, when the aspect ratio for the detector die transparent cavity block 755 is increased, the trend is toward only allowing light that is substantially collimated and perpendicular 631 to the die 630 to reach the detector die.

The amount of perpendicularity and collimation can be changed by changing the dimensions of the apertures 780, 785 and/or changing height of the mold compound 790. For example, if the aperture dimensions 780, 785 are significantly reduced for a fixed mold compound height, then the light that is able to leave the emitter aperture 725 must be more perpendicular to the die surface. Similarly, if the dimensions for the detecter aperture 735 are reduced for a fixed mold compound height, then the light that is received by the detector die must be more perpendicular to the die surface. Likewise, if the height of the mold 790 is increased and the dimensions of the apertures remain unchanged, the amount of required perpendicularity and collimation for each die will increase. However, those of skill in the art will also understand that the aspect ratio of the die cavity blocks must not be increased so much as to destroy the functionality of the sensor. As the aspect ratio of the cavity blocks are increased, the total amount of light energy leaving the emitter die is attenuated, resulting in less light being reflected from the object and subsequently received by the detector die. Similarly, as the aspect ratio for the detector die cavity block is increased, the amount of light energy that can be received is also attenuated which results in reduced signal output of the detector die, making a “detection” event difficult to resolve.

Another consideration with regard to proximity sensors is the distance between the emitter and detector die 680 and the reflected light angle 795. As the distance between the die 680 is increased the corresponding angle of reflection 795 is commensurately increased. If the angle of reflection is increased too far for a given cavity block aspect ratio, the emitted light energy reflected off the object 660 will not be able to reach the detector die. For the sensor to function properly, the aspect ratios of the two cavity blocks must be designed appropriately such that the emitter can emit adequate light and the detector can receive adequate light so that the object can be detected at the desired distance from the sensor. As mentioned above, proper design of a sensor must also take into account the light noise of the environment as well as the proximity and reflectivity of the object.

FIG. 8 is a simplified diagram of a semiconductor package 801 in accordance with another embodiment of the invention. In this figure, die 620, 630 are attached to a leadframe or substrate 610, and bond wires 840, 845 extend from the die 620, 630 to the leadframe or substrate 610. These steps are not separately illustrated but may be performed in a manner similar to that described above with regard to FIGS. 1A-1G and steps 210-230 of FIG. 2.

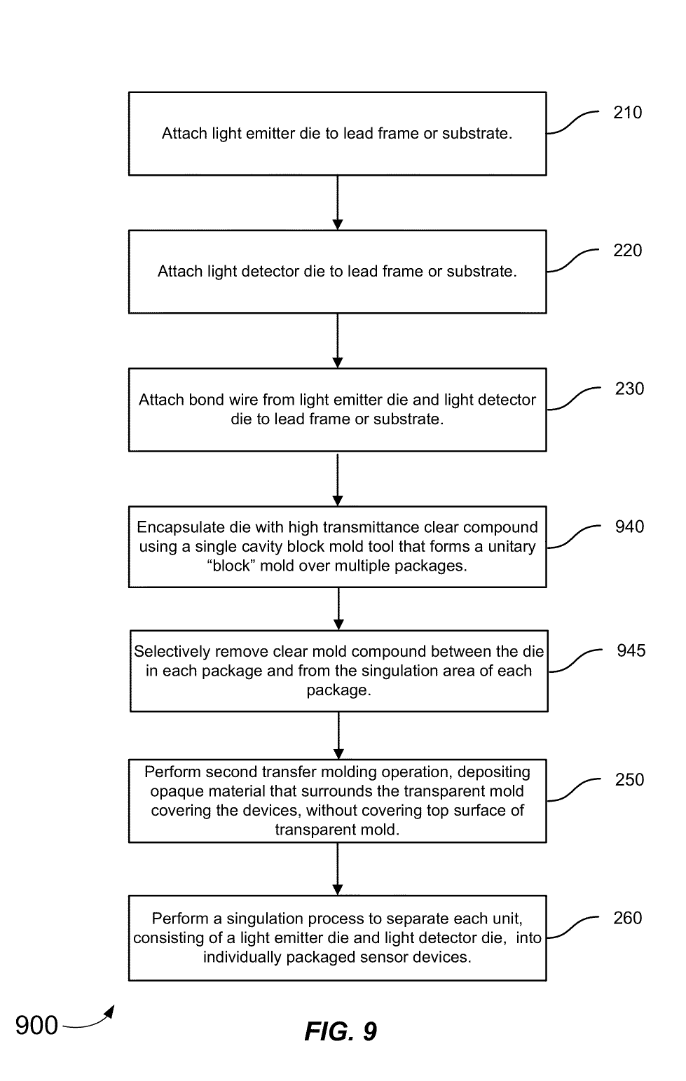

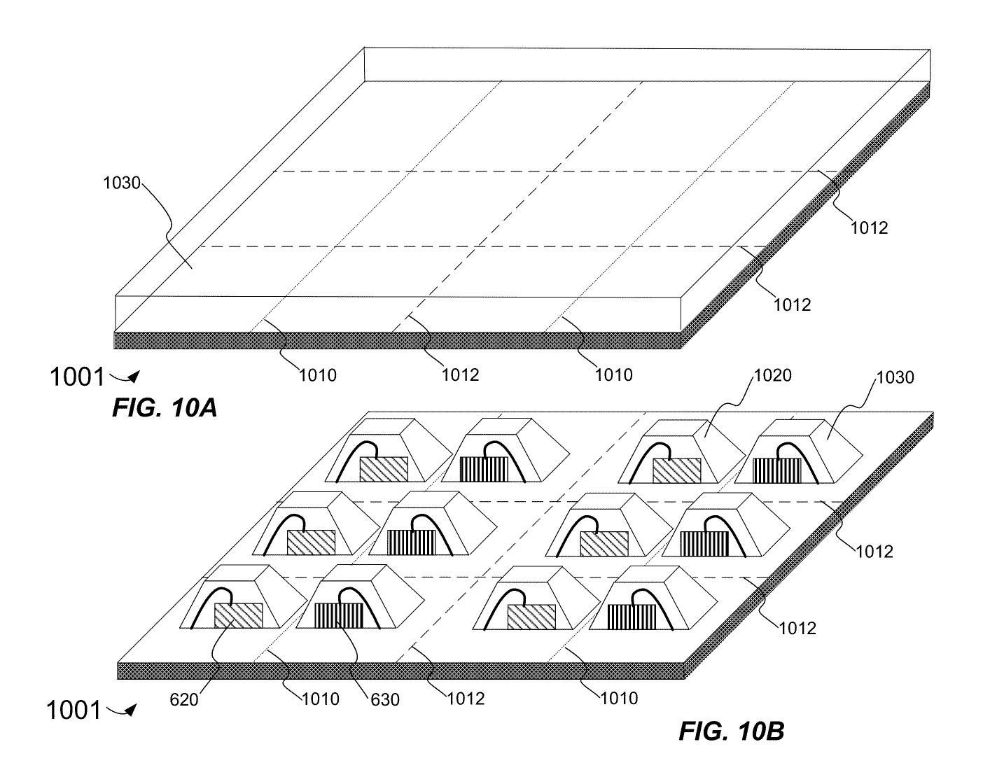

FIG. 9 shows that operations 210, 220 and 230 may be performed as described above in connection with FIG. 2. In step 940, the devices on panel 1001 may be simultaneously molded as a “block” with transparent mold compound 1030 having a coplanar surface over the leadframe, as illustrated in FIG. 10A. In step 945, portions of the block of transparent mold compound are selectively removed. The selective removal of the transparent mold compound can be achieved with a sawing operation, abrasive water jet ablation, laser ablation, grinding and the like. The description of the selective removal process as using a saw will be used herein for exemplary purposes only and in no way limits the invention. FIG. 10B depicts the panel after the selective removal operation. In this embodiment the selective removal operation results in the formation of individual pyramidically shaped cavity blocks of transparent mold compound over the emitter and detector die, two of which 1020, 1030 are identified for purposes of illustration.

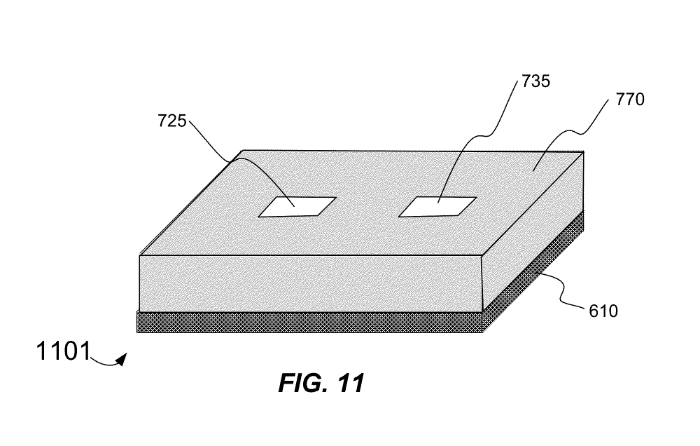

FIG. 10B depicts different selective removal paths 1010, 1012 where different widths of transparent mold compound may be removed. The paths between the die 1010 are narrow removal paths and the paths 1012 between and around the packages are wider removal paths called “streets”. The cavities formed in the transparent mold compound may be called “street” cavities when referring to the panel level assembly and they may be called “edge cavities” when referring to the package level assembly. These terms may also be used interchangeably. Different saw blades can be used to remove different widths of material in the streets. The same effect of varying the path width can also be achieved by using multiple passes of a relatively narrow saw. For example, generally there is a narrow separation between the emitter die and the detector die so a single pass with a thin saw blade can be used. However, between and around the outside of the individual packages, comprising an emitter-detector die pair, there is much more room so either a wide saw blade can be used, or multiple passes with a thin saw blade can be used to form the streets 1012. There are many different shapes of saw blades that can be used in accordance with embodiments of the invention. A tapered blade is depicted here; however other shapes, profiles and combinations thereof can be used without departing from this disclosure. After the transparent mold compound is selectively removed at step 945, the sensor packages are then completed with the same process as described earlier in FIG. 9. In step 250 a second transfer molding operation is performed using opaque mold compound and finally, in step 260, the individual packages 1101 are singulated, providing an encapsulated emitter-detector pair, as depicted in FIG. 11. If a narrow singulation blade is used then some of the opaque mold compound disposed within the streets may remain on one or more edges of the package creating an opaque barrier. However if a wide singulation blade is used, then there may be no opaque material remaining on the edges of the package.

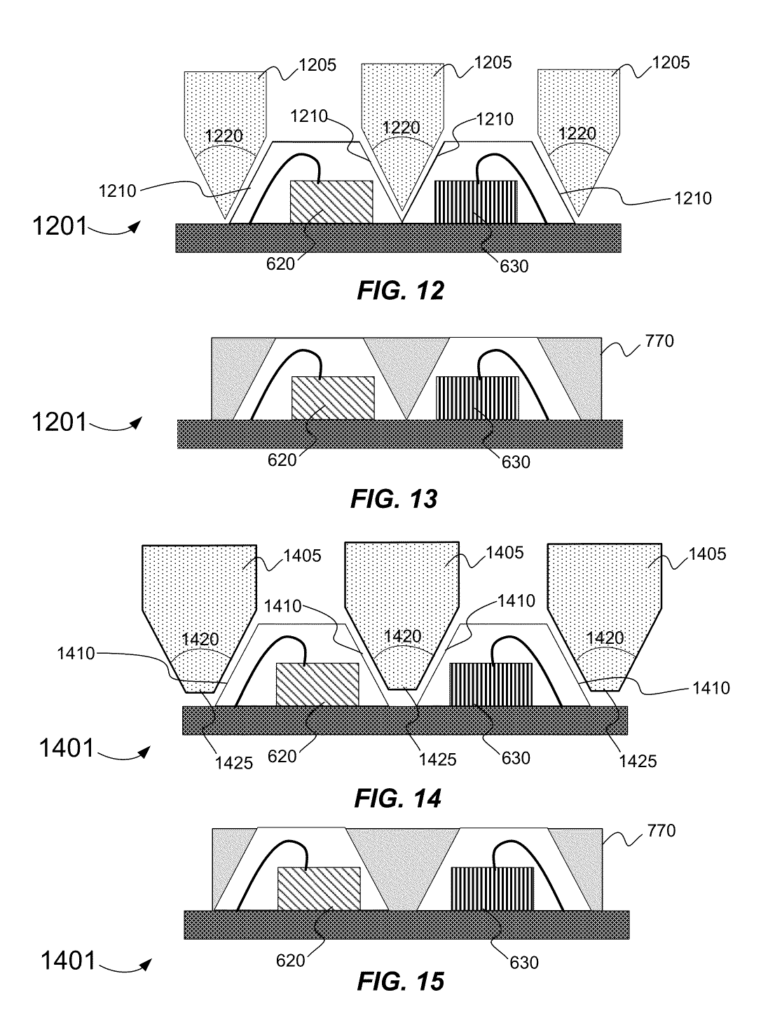

FIGS. 12-22 depict various embodiments employing the manufacturing process 900 described in FIG. 9 for producing the packaged sensor 1101. FIG. 12 depicts a saw blade 1205 with a V-shaped cutting profile and included angle 1220. This blade may be used to remove the transparent molding compound 1030 between the emitter die 620 and the detector die 630, forming a cavity therebetween. This blade may also be used on the periphery of the package in the streets 1012. The use of the V-shaped saw blade creates sloped surfaces 1210 on the transparent mold compound. Employing this saw 1205 in both the vertical and horizontal paths on the panel results in the formation of pyramidically shaped transparent cavity blocks 1020, 1030 over the emitter and detector die. As depicted in FIG. 13, after the selective removal process, the sensor packages 1201 may be completed with the process 900 as described in FIG. 9, comprising steps 250 and 260. In step 250, opaque mold compound 770 is disposed between and coplanar with the transparent cavity blocks, and in step 260 the packages are singulated. If a narrow singulation blade is used then some of the opaque mold compound disposed within the streets may remain on one or more edges of the package creating an opaque barrier. However if a wide singulation blade is used, then there may be no opaque material remaining on the edges of the package.

FIG. 14 depicts a saw blade 1405 with a V-shaped cutting profile with included angle 1420 and a blunt tip 1425. This blade may be used to remove the transparent molding compound 1030 between the emitter die 620 and the detector die 630, forming a cavity therebetween. This blade may also be used on the periphery of the package 1401. One benefit of the V-shaped blade with the blunt tip is that it may require fewer passes around the periphery of the package to selectively remove portions of the transparent mold compound. Because the blade 1425 is V-shaped, it creates sloped surfaces 1410 on the transparent mold compound. Employing this saw in both the vertical and horizontal directions results in the formation of pyramidically shaped transparent cavity blocks over the emitter and detector die. As depicted in FIG. 15, the sensor packages 1401 may be completed with the process 900 as described in FIG. 9. In step 250 opaque mold compound 770 is disposed between and coplanar with the transparent cavity blocks, and in step 260 the packages are singulated. If a narrow singulation blade is used then some of the opaque mold compound disposed within the streets may remain on one or more edges of the package creating an opaque barrier. However if a wide singulation blade is used, then there may be no opaque material remaining on the edges of the package.

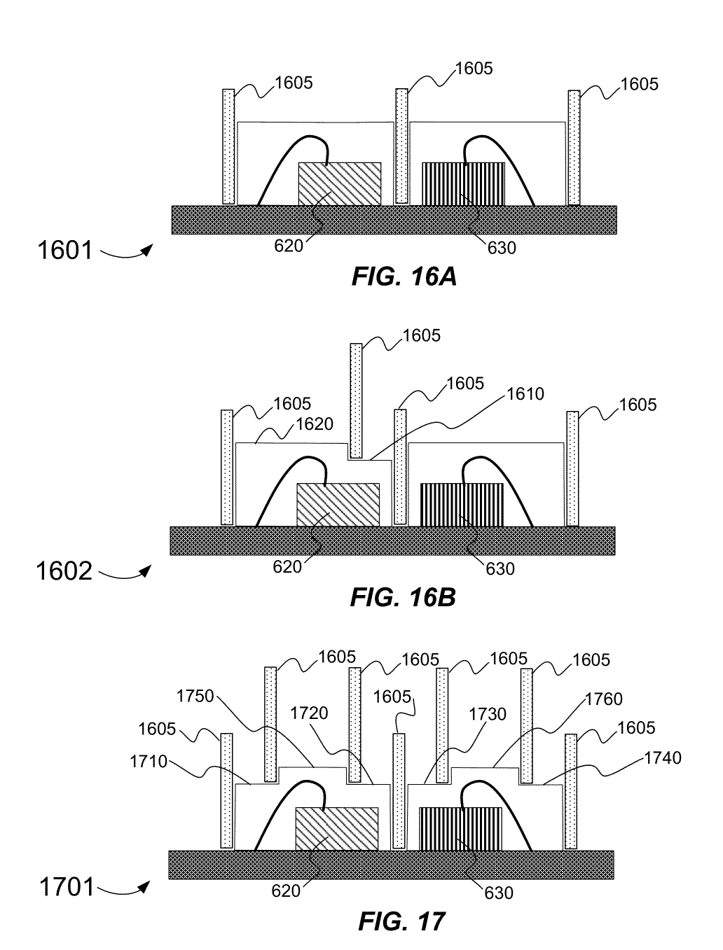

FIG. 16A depicts a saw blade 1605 with a rectangular cutting profile. This blade may be used to remove the transparent molding compound 1030 between the emitter die 620 and the detector die 630, forming a cavity therebetween. The same blade can be used around the periphery of the package 1601 in the streets. As depicted in FIG. 10B, the amount of transparent mold compound removed in the streets 1012 may be greater than the amount removed between the die 1010. To remove a greater amount of mold compound in the streets, a thicker blade may be employed or multiple passes with a thin blade may be used. Employing the sawing operation in both the vertical and horizontal directions results in the formation of cubically shaped transparent cavity blocks over each die. The sensor packages 1601 may be completed with the process 900 as described in FIG. 9. In step 250 opaque mold compound 770 is disposed between and coplanar with the transparent cavity blocks, and in step 260 the packages are singulated. If a narrow singulation blade is used then some of the opaque mold compound disposed within the streets may remain on one or more edges of the package creating an opaque barrier. However if a wide singulation blade is used, then there may be no opaque material remaining on the edges of the package.

FIG. 16B depicts a saw blade 1605 with a rectangular cutting profile. This blade may be used to remove the transparent molding compound 1030 between the emitter die 620 and the detector die 630, forming a cavity therebetween. The blade may be set to a reduced depth and used to create a ledge cavity 1610 over the emitter die 620 thereby creating a reduced emitting aperture 1620 over the emitter die 620. The same blade may be used around the periphery of the package 1602 in the streets. Employing this saw in both the vertical and horizontal directions results in the formation of cubically shaped transparent cavity blocks over each die with a reduced aperture over the emitter die. The sensor packages 1601 may be completed with the process 900 as described in FIG. 9. In step 250 opaque mold compound 770 is disposed between and coplanar with the transparent cavity blocks, and in step 260 the packages are singulated. If a narrow singulation blade is used then some of the opaque mold compound disposed within the streets may remain on one or more edges of the package creating an opaque barrier. However if a wide singulation blade is used, then there may be no opaque material remaining on the edges of the package.

FIG. 17 depicts a saw blade 1605 with a rectangular cutting profile. This blade may be used to remove the transparent molding compound 1030 between the emitter die 620 and the detector die 630, forming a cavity therebetween. The blade can be set to a reduced depth and used to create ledge cavities 1710, 1720, 1730, 1740 over the emitter and detector die 620, 630 thereby creating reduced emitting and receiving apertures 1750, 1760. The same blade may be used around the periphery of the package 1701. Employing this saw in both the vertical and horizontal directions results in the formation of cubically shaped transparent cavity blocks with reduced apertures over the emitter and detector die. The sensor packages 1701 may be completed with process 900 as described in FIG. 9. In step 250 opaque mold compound 770 is disposed between and coplanar with the transparent cavity blocks, and in step 260 the packages are singulated. If a narrow singulation blade is used then some of the opaque mold compound disposed within the streets may remain on one or more edges of the package creating an opaque barrier. However if a wide singulation blade is used, then there may be no opaque material remaining on the edges of the package.

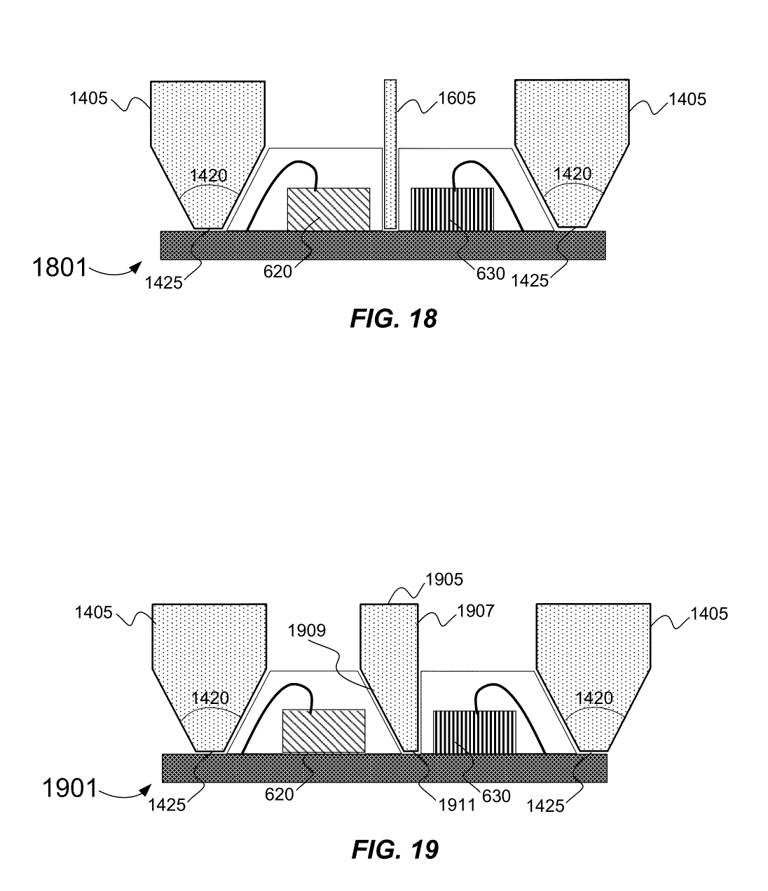

FIG. 18 depicts an embodiment employing a combination of saw blades. A saw blade with a rectangular cutting profile 1605 may be used to remove the transparent molding compound 1030 between the emitter die 620 and the detector die 630, forming a cavity therebetween. A separate saw blade 1405, with a V-shaped cutting profile with included angle 1420 and a blunt tip 1425, may be used to remove the transparent mold compound around the periphery of the package 1801 in the streets. Employing this method results in the ability to locate the emitter die in close proximity to the detector die, while also creating reduced apertures for the die. The sensor packages 1801 may be completed with the process 900 as described in FIG. 9. In step 250 opaque mold compound 770 is disposed between and coplanar with the transparent cavity blocks, and in step 260 the packages are singulated. If a narrow singulation blade is used then some of the opaque mold compound disposed within the streets may remain on one or more edges of the package creating an opaque barrier. However if a wide singulation blade is used, then there may be no opaque material remaining on the edges of the package.

FIG. 19 depicts an embodiment employing a combination of saw blades. A saw blade 1905 with one vertical cutting surface 1907, one angled vertical cutting surface 1909 and a blunt tip 1911, may be used to remove the transparent molding compound 1030 between the emitter die 620 and the detector die 630, forming a cavity therebetween. A separate saw blade 1405 with a V-shaped cutting profile with included angle 1420 and a blunt tip 1425, may be used to remove the transparent mold compound around the periphery of the package 1901 in the streets. The sensor packages 1901 may be completed with the process 900 as described in FIG. 9. In step 250 opaque mold compound 770 is disposed between and coplanar with the transparent cavity blocks, and in step 260 the packages are singulated. If a narrow singulation blade is used then some of the opaque mold compound disposed within the streets may remain on one or more edges of the package creating an opaque barrier. However if a wide singulation blade is used, then there may be no opaque material remaining on the edges of the package.

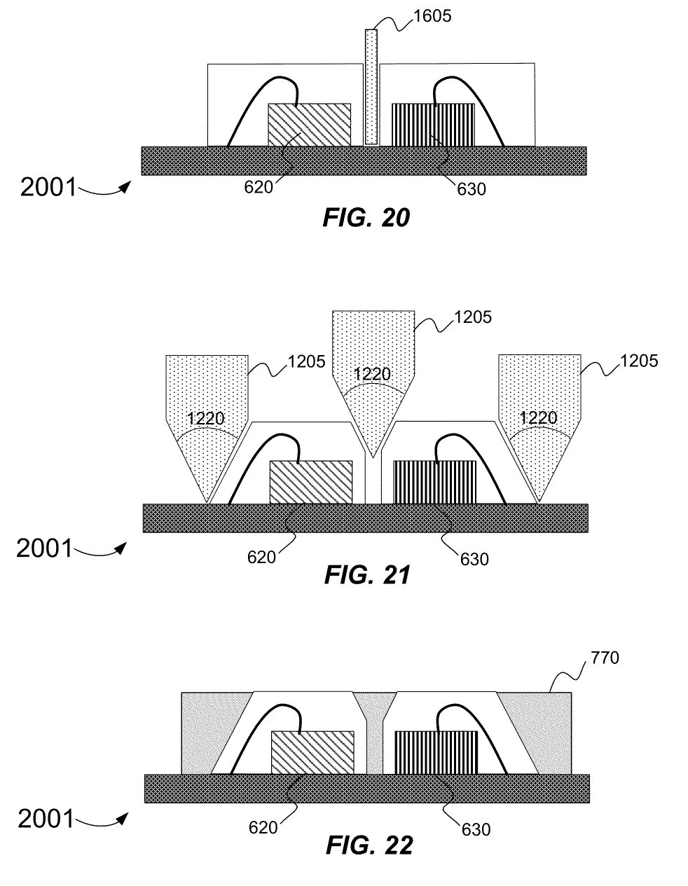

FIGS. 20-22 depict an embodiment employing a combination of saw blades as well as a successive sawing process. This embodiment may be beneficial when the distance between the die 620, 630 is reduced. First, as depicted in FIG. 20, a saw blade 1605 with a rectangular cutting profile may be used to remove the transparent molding compound 1030 between the emitter die 620 and the detector die 630, forming a cavity therebetween. FIG. 21 depicts a sawing operation, wherein a saw blade 1205 with a V-shaped cutting profile and included angle 1220 may be used. This blade may be set to a reduced cutting depth and used between the emitter die 620 and the detector die 630 to remove additional transparent molding compound forming a ledge cavity adjacent to the previously formed cavity. This combination of sawing operations between the die creates a cavity for an opaque barrier, and simultaneously creates reduced transmitting and receiving apertures over die 620, 630. The same V-shaped blade 1205 may also be used on the periphery of the package 2001 at the full cutting depth to remove the transparent mold compound in the streets. As depicted in FIG. 22, the sensor packages 2001 may be completed with the process 900 as described in FIG. 9. In step 250 opaque mold compound 770 is disposed between and coplanar with the transparent cavity blocks, and in step 260 the packages are singulated. If a narrow singulation blade is used then some of the opaque mold compound disposed within the streets may remain on one or more edges of the package creating an opaque barrier. However if a wide singulation blade is used, then there may be no opaque material remaining on the edges of the package.

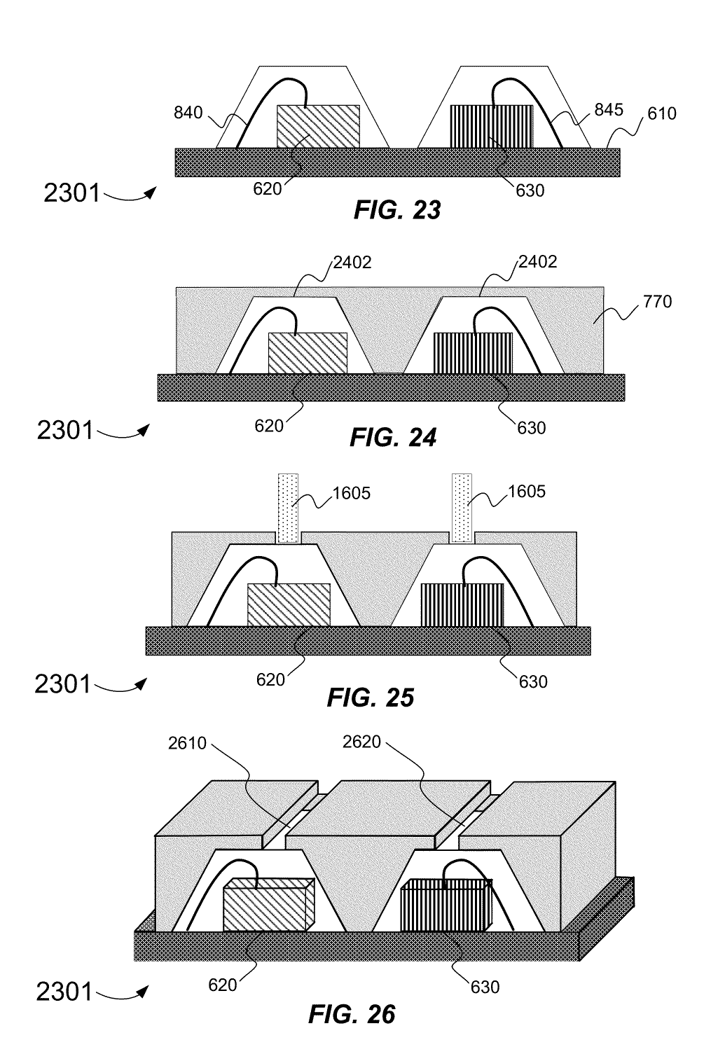

FIGS. 23-26 are simplified diagrams of a semiconductor package 2301 in accordance with another embodiment of the invention. In FIG. 23, dies 620, 630 are attached to a leadframe or substrate 610, and bond wires 840, 845 extend from the die 620, 630 to the leadframe or substrate 610. These steps are not separately illustrated but may be performed in a manner similar to that described above with regard to FIGS. 1A-1G and steps 210-230 of FIG. 2.

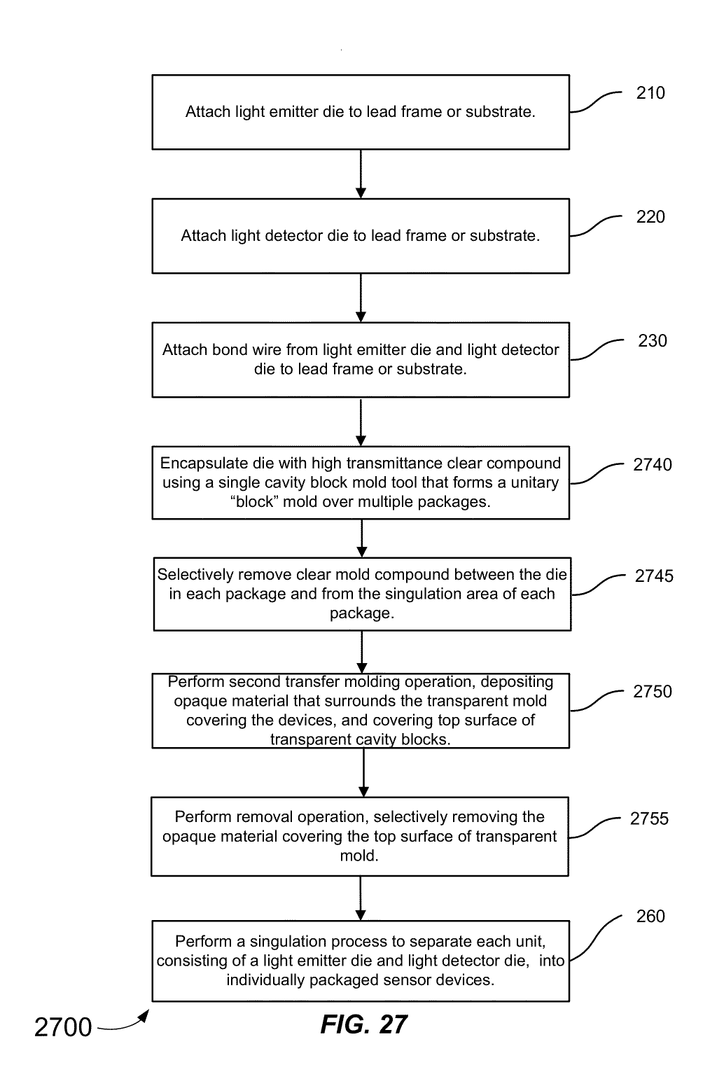

FIG. 27 shows that operations 210, 220 and 230 may be performed as described above in connection with FIG. 2. In step 2740, the devices on panel 1001 may be simultaneously molded as a “block” with transparent mold compound 1030 having a coplanar surface over the leadframe, as illustrated in FIG. 10A. In step 2745, portions of the block of transparent mold compound are selectively removed. The selective removal of the transparent mold compound can be achieved with a sawing operation, abrasive water jet ablation, laser ablation, grinding and the like. The description of the selective removal process as using a saw will be used herein for exemplary purposes only and in no way limits the invention. FIG. 10B shows the panel after the selective removal operation. In this embodiment the selective removal operation results in the formation of individual pyramidically shaped cavity blocks of transparent mold compound over the emitter and detector die, two of which 1020, 1030 are identified for purposes of illustration.

FIG. 10B depicts different selective removal paths 1010, 1012 where different widths of transparent mold compound may be removed. The paths between the die 1010 are narrow removal paths and the paths 1012 between and around the packages are wider removal paths called “streets”. Different saw blades can be used to remove different widths of material. The same effect of varying the path width can also be achieved by using multiple passes of a relatively narrow saw. For example, generally there is a narrow separation between the emitter die and the detector die so a single pass with a thin saw blade can be used. However, between and around the outside of the individual packages, comprising an emitter-detector die pair, there is much more room so either a wide saw blade can be used, or multiple passes with a thin saw blade can be used to form the streets 1012. There are many different shapes of saw blades that can be used in accordance with embodiments of the invention. A tapered blade is depicted here; however other shapes, profiles and combinations thereof can be used without departing from this disclosure.

Referring back to the process 2700 in FIG. 27, in step 2750 a second transfer molding operation using opaque mold compound may be performed. FIG. 24 depicts the cross-section of the package after the opaque molding process. Opaque mold compound 770 may be disposed on all four sides of each transparent cavity block and additionally on top of each cavity block 2402. In step 2755 a saw blade, 1605 with a rectangular profile may be used at a reduced cutting depth to selectively remove the opaque mold compound, exposing the transparent mold compound below (FIG. 25). As illustrated in FIG. 26, this process forms an emitting aperture 2610 over the emitter die 620 and a receiving aperture 2620 over the detector die 630. By using this process the aperture dimensions can be controlled. The opaque molding process for this embodiment may not require coplanarity with the transparent cavity blocks. In this embodiment a simple standard cavity block mold tool can be used to over mold the entire panel. In one embodiment the sawing operation may simultaneously polish the apertures during the sawing operation. In an alternative embodiment, the apertures may be polished with a subsequent operation. In step 260, the sensor packages 2301 may be completed with the singulation process providing an encapsulated emitter-detector pair. If a narrow singulation blade is used then some of the opaque mold compound disposed within the streets may remain on one or more edges of the package creating an opaque barrier. However if a wide singulation blade is used, then there may be no opaque material remaining on the edges of the package.

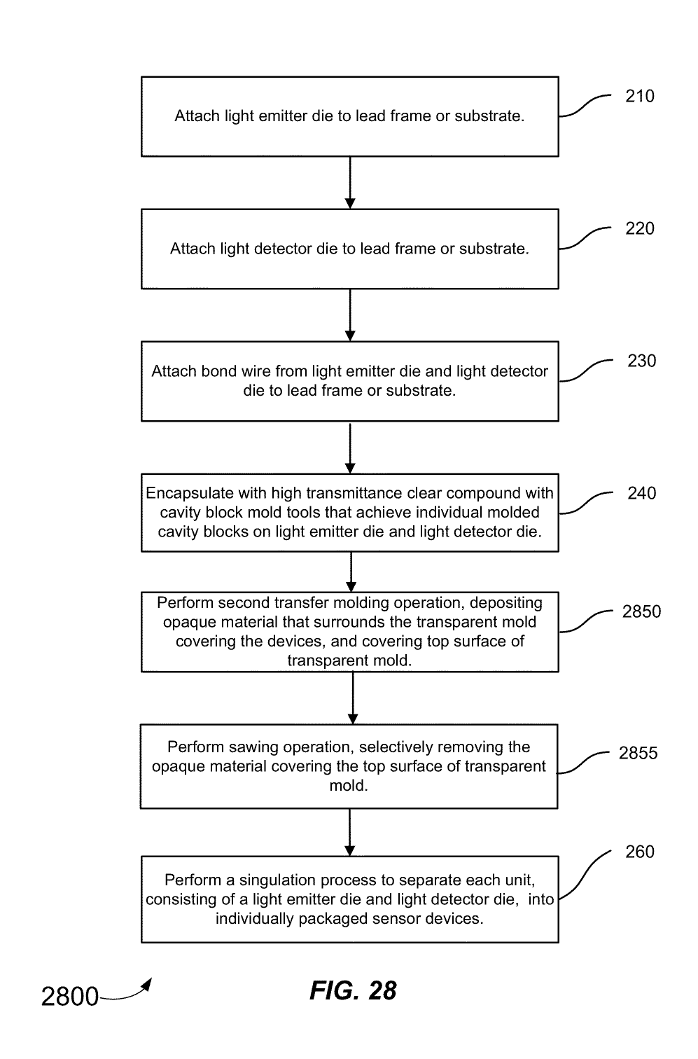

FIG. 28 describes an alternative process 2800 for manufacturing the embodiment depicted in FIGS. 23-26. FIGS. 23-26 are simplified diagrams of a semiconductor package 2301 in accordance with this embodiment. In FIG. 23, dies 620, 630 are attached to a leadframe or substrate 610, and bond wires 840, 845 extend from the die 620, 630 to the leadframe or substrate 610. The emitter die and the detector die are subsequently individually encapsulated in transparent mold compound cavity blocks. These steps are not separately illustrated but may be performed in a manner similar to that described above with regard to FIGS. 1A-1G and steps 210-240 of FIG. 2.

FIG. 28 shows that operations 210, 220, 230 and 240 may be performed as described above in connection with FIG. 2. In this embodiment the selective encapsulation process results in the formation of individual pyramidically shaped cavity blocks of transparent mold compound over the emitter and detector die, two of which 1020, 1030 are identified for purposes of illustration.

Referring back to the process 2800 in FIG. 28, in step 2850 a second transfer molding operation using opaque mold compound may be performed. FIG. 24 depicts the cross-section of the package after the opaque molding process. Opaque mold compound 770 may be disposed on all four sides of each transparent cavity block and additionally on top of each cavity block 2402. In step 2855 a saw blade, 1605 with a rectangular profile may be used at a reduced cutting depth selectively removing the opaque mold compound, exposing the transparent mold compound below (FIG. 25). As illustrated in FIG. 26, this process forms an emitting aperture 2610 over the emitter die 620 and a receiving aperture 2620 over the detector die 630. By using this process the aperture dimensions can be controlled. The opaque molding process for this embodiment may not require coplanarity with the transparent cavity blocks. In this embodiment a simple standard cavity block mold tool can be used to over mold the entire panel. In one embodiment the sawing operation may simultaneously polish the apertures during the sawing operation. In an alternative embodiment, the apertures may be polished with a subsequent operation. In step 260, the sensor packages 2301 may be completed with the singulation process providing an encapsulated emitter-detector pair. If a narrow singulation blade is used then some of the opaque mold compound disposed within the streets may remain on one or more edges of the package creating an opaque barrier. However if a wide singulation blade is used, then there may be no opaque material remaining on the edges of the package.

It should be noted that although the embodiments illustrated include the use of one particular saw blade shape or a combination of particular saw blade shapes that other configurations can be manufactured using the principles disclosed herein. Many different configurations, shapes and sequences of saw blades can be employed as needed as would be appreciated by one of ordinary skill in the art with the benefit of this disclosure.

It should be noted that although many of the embodiments illustrated may only depict the use of a saw blade between the die and on two opposite sides of the package, it should be appreciated that the sawing operation may be performed on all four sides of the package using the principles disclosed herein. It should also be noted that although some embodiments may be illustrated using a sawing process to selectively remove the transparent mold compound, and other embodiments may be illustrated using the molding process to selectively dispose the transparent mold compound, that combinations thereof may be employed as needed. For example, cubically shaped cavities of transparent mold compound may be molded over individual die and sawing operations may be subsequently used to shape or add a slope to those cubes. Many different configurations, shapes and sequences of molding and sawing operations can be employed as needed as would be appreciated by one of ordinary skill in the art with the benefit of this disclosure.

It should be appreciated that the specific steps illustrated in FIGS. 2, 9, 27-28 provide particular methods of forming a semiconductor package, according to embodiments of the present invention. Other sequences of steps may also be performed according to alternative embodiments. In certain embodiments, the methods may perform the individual steps in a different order, at the same time, or any other sequence for a particular application. Moreover, the individual steps illustrated in FIGS. 2, 9, 27-28 may include multiple sub-steps that may be performed in various sequences as appropriate to the individual step. Furthermore, additional steps may be added or removed depending on the particular applications. One of ordinary skill in the art would recognize and appreciate many variations, modifications, and alternatives in light of the methods.

It should be noted that although the embodiments illustrated include one emitter die and one detector die, other configurations can be manufactured using the principles disclosed herein. For example, some embodiments may include multiple light emitters and one or more detectors. Many different configurations and shapes of the transparent compound cavities can be formed as needed as would be appreciated by one of ordinary skill in the art with the benefit of this disclosure. Furthermore, the multi-compound molding process described herein can be processed through automated transfer molding methods which are productive and cost effective and provide a robust process to ramp production to a high volume manufacturing capacity in a much shorter lead time than current die casting processes, while achieving high manufacturing yields.

It should be appreciated that the semiconductor packages shown in the figures and described in the description above are for illustrative purposes and the methods and structures described herein may be applied to a number of different types of semiconductor packages. Some of these semiconductor packages may include quad-flat no-leads (QFN) packages, dual-flat no-leads (DFN) packages, micro leadframe packages (MLPs), and other packages that would be known and appreciated by one of ordinary skill in the art with the benefit of this disclosure. Furthermore, the various features shown in the figures are not intended to be drawn to scale.

While the present invention has been described in terms of specific embodiments, it should be apparent to those skilled in the art that the scope of the present invention is not limited to the embodiments described herein. For example, features of one or more embodiments of the invention may be combined with one or more features of other embodiments without departing from the scope of the invention. The specification and drawings are, accordingly, to be regarded in an illustrative rather than a restrictive sense. Thus, the scope of the present invention should be determined not with reference to the above description but with reference to the appended claims along with their full scope of equivalents.

It should be noted that certain embodiments of the present invention can perform some or all of the functions described herein. For example, some embodiments can perform all of the functions described in FIGS. 1A-5D, while others may be limited to one or two of the various functions described herein.

Any recitation of “a”, “an” or “the” is intended to mean “one or more” unless specifically indicated to the contrary.

The above description is illustrative and is not restrictive. Many variations of the invention will become apparent to those skilled in the art upon review of the disclosure. The scope of the invention should, therefore, be determined not with reference to the above description, but instead should be determined with reference to the pending claims along with their full scope or equivalents.

1.-22. (canceled)

23. A semiconductor package comprising:
a leadframe;
a first die disposed on the leadframe;
a second die disposed on the leadframe adjacent to the first die;
a transparent material disposed over the first and second die;
a first cavity in the transparent material, disposed between the first die and the second die and above the leadframe;
at least one edge cavity in the transparent material, disposed on an edge of the package and above the leadframe; and
an opaque material disposed within the first cavity and the edge cavity.

24. The semiconductor package of claim 23 wherein the opaque material is substantially flush with respect to a top surface of the transparent material.

25. The semiconductor package of claim 23 wherein the opaque material is additionally disposed on a top surface of the transparent material; and
wherein at least a portion of the opaque material disposed on the top surface of the transparent material is selectively removed.

26. The semiconductor package of claim 23 further comprising edge cavities in the transparent material, disposed on each of the four edges of the package and above the leadframe; and
the opaque material disposed within the plurality of edge cavities.

27. The semiconductor package of claim 23 further comprising at least one ledge cavity in the transparent material, disposed adjacent to the first cavity; and
the opaque material disposed within the ledge cavity.

28. The semiconductor package of claim 23 wherein the first cavity has at least one sloped wall.

29. A semiconductor package comprising:
a leadframe;
a first die disposed on the leadframe;
a second die disposed on the leadframe adjacent to the first die;
a transparent material disposed over the first and second die;
a first cavity disposed within the transparent material between the first die and the second die and above the leadframe;
wherein the first cavity has at least one sloped wall; and
an opaque material disposed in the first cavity.

30. The semiconductor package of claim 29 wherein the opaque material is substantially flush with respect to a top surface of the transparent material.

31. The semiconductor package of claim 29 wherein the opaque material is additionally disposed on a top surface of the transparent material; and
wherein at least a portion of the opaque material disposed on the top surface of the transparent material is selectively removed.

32. The semiconductor package of claim 29 further comprising edge cavities in the transparent material, disposed on each of the four edges of the package and above the leadframe; and
the opaque material disposed within the plurality of edge cavities.

33. The semiconductor package of claim 29 further comprising at least one ledge cavity in the transparent material, disposed adjacent to the first cavity; and
the opaque material disposed within the ledge cavity.

34. A method of forming a semiconductor package, the method comprising:
providing a leadframe;
placing a first die on the leadframe;
placing a second die on the leadframe, wherein the first and second die are placed adjacent to each other;
disposing a transparent material over the first and second die;
forming a first cavity between the first die and the second die and above the leadframe;
forming at least one street cavity in the transparent material, disposed on a street and above the leadframe; and
disposing an opaque material within the first cavity and the street cavity.

35. The method of claim 34 wherein the street cavity is wider than the first cavity.

36. The method of claim 34 wherein the opaque material is additionally disposed on a top surface of the transparent material; and
selectively removing at least a portion of the opaque material disposed on the top surface of the transparent material.

37. The method of claim 34 further comprising forming street cavities in the transparent material, disposed on each of the horizontal and vertical streets and above the leadframe; and
the opaque material disposed within the plurality of street cavities.

38. The method of claim 34 further comprising forming at least one ledge cavity in the transparent material;
wherein the ledge cavity is disposed adjacent to the first cavity; and
disposing the opaque material within the ledge cavity.

39. The method of claim 34 wherein the first cavity has at least one sloped wall.

40. A method of forming a semiconductor package, the method comprising:
providing a leadframe;
placing a first die on the leadframe;
placing a second die on the leadframe, wherein the first and second die are placed adjacent to each other;
disposing a transparent material over the first and second die;
forming a first cavity having at least one sloped wall between the first die and the second die and above the leadframe;
disposing an opaque material within the first cavity.

41. The method of claim 40 further comprising forming street cavities in the transparent material, disposed on each of the horizontal and vertical streets and above the leadframe; and
the opaque material disposed within the plurality of street cavities.

42. The method of claim 40 further comprising forming at least one ledge cavity in the transparent material;
wherein the ledge cavity is disposed adjacent to the first cavity; and
disposing the opaque material within the ledge cavity.
